(19) United States
(12) Patent Application Publication
(10) Pub. No.: US 2025/0379383 A1
(43) Pub. Date: Dec. 11, 2025

(54) CIRCUIT BOARD, LIQUID JET HEAD, AND LIQUID JET RECORDING APPARATUS

(71) Applicant: SII Printek Inc., Chiba-shi (JP)

(72) Inventor: Yukihiro Saga, Chiba-shi (JP)

(21) Appl. No.: 19/226,573

(22) Filed: Jun. 3, 2025

(30) Foreign Application Priority Data
Jun. 7, 2024 (JP) 2024-092726

(51) Int. Cl. H01R 12/79; B41J 2/14; H01R 13/629; H05K 1/02

(52) U.S. Cl. CPC H01R 12/79; B41J 2/14; H01R 13/629; H05K 1/0269; H05K 1/0281; B41J 2002/14491

(57) ABSTRACT

A circuit board and so on capable of increasing the reliability while avoiding a rise in cost are provided. The circuit board according to an embodiment of the present disclosure is a circuit board configured to output a drive signal to be applied to a liquid jet head, including a first circuit board having a connector, and a second circuit board having a terminal section as a portion to be inserted into the connector. A first marking portion which is an index when visually confirming a coupling state between the connector and the terminal section is disposed on the first circuit board, and a second marking portion which is an index when visually confirming the coupling state is disposed on the second circuit board.

### RELATED APPLICATIONS

This application claims priority to Japanese Patent application No. JP2024-092726, filed on Jun. 7, 2024, the entire content of which is incorporated herein by reference.

### BACKGROUND OF THE INVENTION

### 1. Field of the Invention

The present disclosure relates to a circuit board, a liquid jet head, and a liquid jet recording apparatus.

### 2. Description of Related Art

Liquid jet recording apparatuses equipped with liquid jet heads are used in a variety of fields, and a variety of types of liquid jet heads have been developed (see, e.g., JP2007-203573A).

In such a liquid jet head, in general, it is required to enhance the reliability. Therefore, it is desirable to provide a circuit board, a liquid jet head, and a liquid jet recording apparatus capable of enhancing the reliability while preventing a rise in cost.

### SUMMARY OF THE INVENTION

A circuit board according to an embodiment of the present disclosure is a circuit board configured to output a drive signal to be applied to a liquid jet head, including a first circuit board having a connector, and a second circuit board having a terminal section as a portion to be inserted into the connector.

A first marking portion which is an index when visually confirming a coupling state between the connector and the terminal section is disposed on the first circuit board, and a second marking portion which is an index when visually confirming the coupling state is disposed on the second circuit board.

The liquid jet head according to an embodiment of the present disclosure includes the circuit board according to the embodiment of the present disclosure, and a jet section which is configured to jet a liquid based on the drive signal output from the circuit board, and which has a plurality of nozzles.

A liquid jet recording apparatus according to an embodiment of the present disclosure includes the liquid jet head according to the embodiment of the present disclosure.

According to the circuit board, the liquid jet head, and the liquid jet recording apparatus related to an embodiment of the disclosure, it becomes possible to increase the reliability while avoiding a rise in cost.

### BRIEF DESCRIPTION OF THE DRAWINGS

FIG. 1 is a block diagram showing an outline configuration example of a liquid jet apparatus according to an embodiment of the present disclosure.

FIG. 2 is a perspective view schematically showing an outline configuration example of a liquid jet head shown in FIG. 1.

FIG. 3 is a cross-sectional view schematically showing a configuration example of the liquid jet head shown in FIG. 2.

FIG. 4 is a plan view schematically showing an outline configuration example of flexible boards shown in FIG. 2 and FIG. 3.

FIG. 5 is a cross-sectional view schematically showing an outline configuration example of the flexible board shown in FIG. 4.

FIG. 6 is a schematic plan view illustrating coupling between the boards according to the embodiment.

FIG. 7 is another schematic plan view illustrating coupling between the boards according to the embodiment.

FIG. 8 is a schematic plan view illustrating coupling between boards according to Modified Example 1.

FIG. 9 is a schematic plan view illustrating coupling between boards according to Modified Example 2.

FIG. 10 is a schematic plan view illustrating coupling between boards according to Modified Example 3.

FIG. 11 is a schematic plan view illustrating coupling between boards according to Modified Example 4.

FIGS. 12A, 12B and 12C are schematic plan views illustrating coupling between boards according to Modified Examples 5-1, 5-2, and so on.

### DETAILED DESCRIPTION OF THE PREFERRED EMBODIMENTS

An embodiment of the present disclosure will hereinafter be described in detail with reference to the drawings. It should be noted that the description will be presented in the following order.
1. Embodiment (an example in which a first circuit board is a rigid board, and a second circuit board is a flexible board)
2. Modified Examples (Modified Examples 1 to 4, 5-1, and 5-2 are other configuration examples of a circuit board)
3. Other Modified Examples

### 1. Embodiment

### [Outline Configuration of Printer 5]

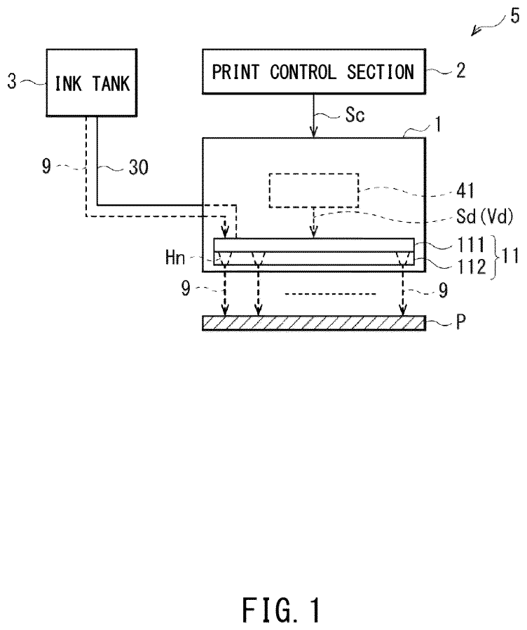

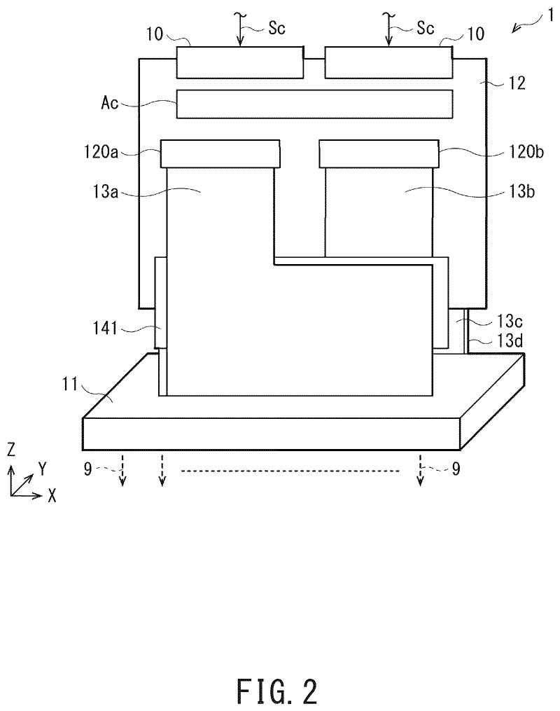

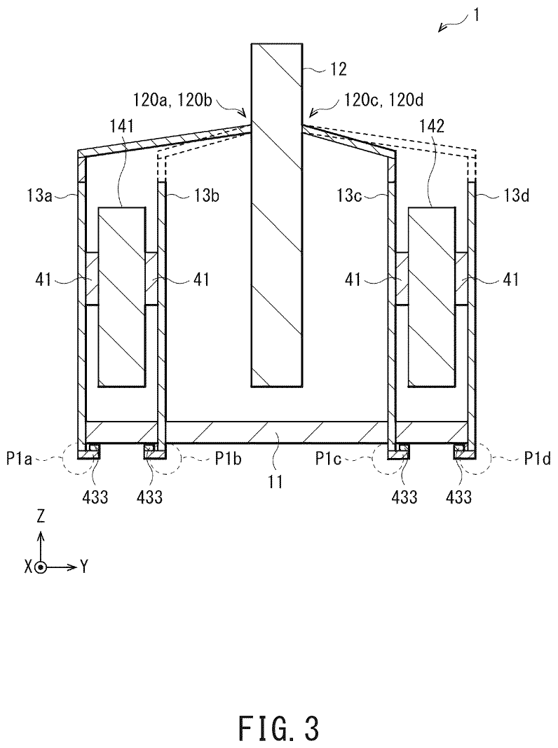

FIG. 1 is a block diagram showing an outline configuration example of a printer 5 as a liquid jet recording apparatus according to an embodiment of the present disclosure. FIG. 2 is a perspective view schematically showing an outline configuration example of an inkjet head 1 as a liquid jet head shown in FIG. 1. FIG. 3 is a cross-sectional view (a Y-Z cross-sectional view) schematically showing a configuration example of the inkjet head 1 shown in FIG. 2. It should be noted that a scale size of each of the members is accordingly altered so that the member is shown in a recognizable size in the drawings used in the description of the present specification.

The printer 5 is an inkjet printer for performing recording (printing) of images, characters, and the like on a recording target medium (e.g., recording paper P shown in FIG. 1) using ink 9 described later. As shown in FIG. 1, the printer 5 is provided with the inkjet head 1, a print control unit 2, and an ink tank 3.

It should be noted that the inkjet head 1 corresponds to a specific example of a “liquid jet head” in the present disclosure, and the printer 5 corresponds to a specific example of a “liquid jet recording apparatus” in the present disclosure. Further, the ink 9 corresponds to a specific example of a “liquid” in the present disclosure.

### (A. Print Control Unit 2)

The print control unit 2 is for supplying the inkjet head 1 with a variety of types of information (data). Specifically, as shown in FIG. 1, the print control unit 2 is arranged to supply each of constituents (drive devices 41 described later and so on) in the inkjet head 1 with a print control signal Sc. It should be noted that the print control signal Sc is arranged to include, for example, image data, an ejection timing signal, and a power-supply voltage for allowing the inkjet head 1 to operate.

### (B. Ink Tank 3)

The ink tank 3 is a tank for containing the ink 9 inside. As shown in FIG. 1, it is arranged that the ink 9 in the ink tank 3 is supplied to the inside (a jet section 11 described later) of the inkjet head 1 via an ink supply tube 30. It should be noted that such an ink supply tube 30 is formed of, for example, a flexible hose having flexibility.

### (C. Inkjet Head 1)

The inkjet head 1 is a head for jetting (ejecting) the ink 9 shaped like a droplet from a plurality of nozzle holes Hn described later to the recording paper P as represented by dotted arrows in FIG. 1 to thereby perform recording of images, characters, and so on. As shown in, for example, FIG. 2 and FIG. 3, the inkjet head 1 is provided with a single jet section 11, a single I/F (interface) board 12, four flexible boards 13a, 13b, 13c, and 13d each having flexibility, and two cooling units 141, 142.

### (C-1. I/F Board 12)

As shown in FIG. 2 and FIG. 3, the I/F board 12 is provided with two connectors 10, four connectors 120a, 120b, 120c, and 120d, and a circuit arrangement area Ac. It should be noted that a rigid board having rigidity is used as the I/F board 12 in the present embodiment.

As shown in FIG. 2, the connectors 10 are each a part (a connector part) for inputting the print control signal Sc which is described above, and which is supplied from the print control unit 2 toward the inkjet head 1 (the flexible boards 13a, 13b, 13c, and 13d described later). The connectors 120a, 120b, 120c, and 120d are parts (connector parts) for electrically coupling the I/F board 12 and the flexible boards 13a, 13b, 13c, and 13d, respectively.

The circuit arrangement area Ac is an area where a variety of circuits are arranged on the I/F board 12. It should be noted that it is also possible to arrange that such a circuit arrangement area is also disposed in other regions on the I/F board 12.

### (C-2. Jet Section 11)

As shown in FIG. 1, the jet section 11 is a part which has the plurality of nozzle holes Hn, and which jets the ink 9 from these nozzle holes Hn. It is arranged that such jet of the ink 9 is performed in accordance with drive signals Sd (drive voltages Vd) supplied from the drive devices 41 described later on each of the flexible boards 13a, 13b, 13c, and 13d (see FIG. 1).

As shown in FIG. 1, such a jet section 11 is configured including an actuator plate 111 and a nozzle plate 112.

### (Nozzle Plate 112)

The nozzle plate 112 is a plate formed of a film material such as polyimide, or a metal material, and has the plurality of nozzle holes Hn described above as shown in FIG. 1. These nozzle holes Hn are formed side by side at predetermined intervals, and each have, for example, a circular shape. It should be noted that these nozzle holes Hn each correspond to a specific example of a “nozzle” in the present disclosure.

In the example of the jet section 11 shown in FIG. 2, the jet section 11 is configured with a plurality of nozzle arrays (four nozzle arrays) each of which has the plurality of nozzle holes Hn in the nozzle plate 112 arranged along an array direction (an X-axis direction). Further, these four nozzle arrays are arranged side by side along a direction (a Y-axis direction) perpendicular to the array direction.

### (Actuator Plate 111)

The actuator plate 111 is a plate formed of a piezoelectric material such as PZT (lead zirconate titanate). The actuator plate 111 is provided with a plurality of channels (pressure chambers). These channels are each a part for applying pressure to the ink 9, and are arranged side by side so as to be parallel to each other at predetermined intervals. Each of the channels is partitioned with drive walls (not shown) formed of a piezoelectric body, and forms a groove part having a recessed shape in a cross-sectional view.

As such channels, there exist ejection channels for ejecting the ink 9, and dummy channels (non-ejection channels) which do not eject the ink 9. In other words, it is arranged that the ejection channels are filled with the ink 9 on the one hand, but the dummy channels are not filled with the ink 9 on the other hand. It should be noted that it is arranged that filling of each of the ejection channels with the ink 9 is performed via, for example, a flow channel (a common flow channel) commonly communicated with such ejection channels. Further, it is arranged that each of the ejection channels is individually communicated with the nozzle hole Hn in the nozzle plate 112 on the one hand, but each of the dummy channels is not communicated with the nozzle hole Hn on the other hand. These ejection channels and dummy channels are alternately arranged side by side along the array direction (the X-axis direction) described above.

Further, on the inner side surfaces opposed to each other in the drive walls described above, there are respectively disposed drive electrodes. As the drive electrodes, there exist common electrodes disposed on the inner side surfaces facing the ejection channels, and active electrodes (individual electrodes) disposed on the inner side surfaces facing the dummy channels. These drive electrodes and the drive devices 41 described later are electrically coupled to each other via each of the flexible boards 13a, 13b, 13c, and 13d. Thus, it is arranged that the drive voltages Vd (the drive signals Sd) described above are applied to the drive electrodes from the drive devices 41 via each of the flexible boards 13a, 13b, 13c, and 13d (see FIG. 1).

### (C-3. Flexible Boards 13a, 13b, 13c, and 13d)

The flexible boards 13a, 13b, 13c, and 13d are each a board for electrically coupling the I/F board 12 and the jet section 11 to each other as shown in FIG. 2 and FIG. 3. These flexible boards 13a, 13b, 13c, and 13d are arranged to individually control jet actions of the ink 9 in the four nozzle arrays in the nozzle plate 112 described above, respectively. Further, as indicated by the reference symbols P1a, P1b, P1c, and P1d in, for example, FIG. 3, it is arranged that the flexible boards 13a, 13b, 13c, and 13d are folded around places (around pressure-bonding electrode parts 433) where the flexible boards 13a, 13b, 13c, and 13d are coupled to the jet section 11, respectively. It should be noted that it is arranged that electrical coupling between the pressure-bonding electrode parts 433 and the jet section 11 is achieved by, for example, thermocompression bonding using an ACF (Anisotropic Conductive Film). Further, for example, it may be arranged that other flexible boards having only the wiring lines are further ACF-bonded to the flexible boards 13a, 13b, 13c, and 13d, and those other flexible boards and the jet section 11 are ACF-bonded to each other.

On each of such flexible boards 13a, 13b, 13c, and 13d (on a wiring layer at an obverse surface S1 side described later), there is individually mounted the single drive device 41 or a plurality of drive devices 41 (see FIG. 3). These drive devices 41 are each a device for outputting the drive signals Sd (the drive voltages Vd) for jetting the ink 9 from the nozzle holes Hn in the corresponding nozzle array in the jet section 11. Therefore, it is arranged that such drive signals Sd are output from each of the flexible boards 13a, 13b, 13c, and 13d to the jet section 11. It should be noted that such drive devices 41 are each formed of, for example, an ASIC (Application Specific Integrated Circuit).

Further, these drive devices 41 are arranged to be cooled by the cooling units 141, 142 described above. Specifically, as shown in FIG. 3, the cooling unit 141 is fixedly arranged between the drive devices 41 on the flexible boards 13a, 13b, and by pressing the cooling unit 141 against each of these drive devices 41, the drive devices 41 are cooled. Similarly, the cooling unit 142 is fixedly arranged between the drive devices 41 on the flexible boards 13c, 13d, and by pressing the cooling unit 142 against each of these drive devices 41, the drive devices 41 are cooled. It should be noted that such cooling units 141, 142 can each be configured using a variety of types of cooling mechanisms.

[Detailed Configuration of Flexible Boards 13a, 13b, 13c, and 13d]

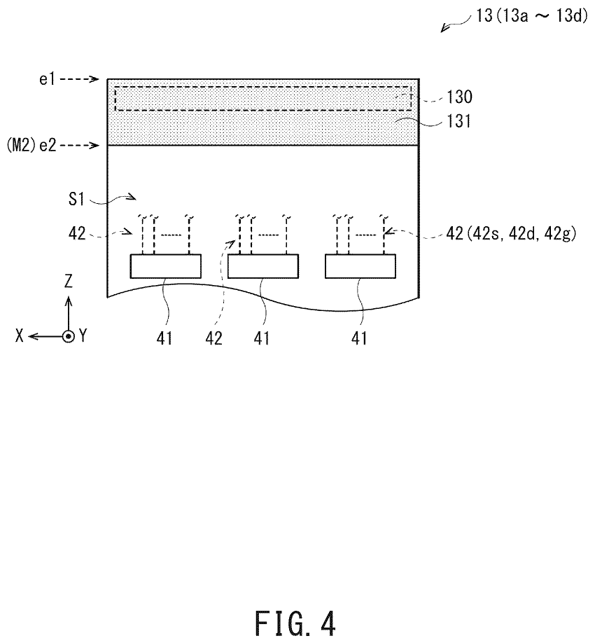

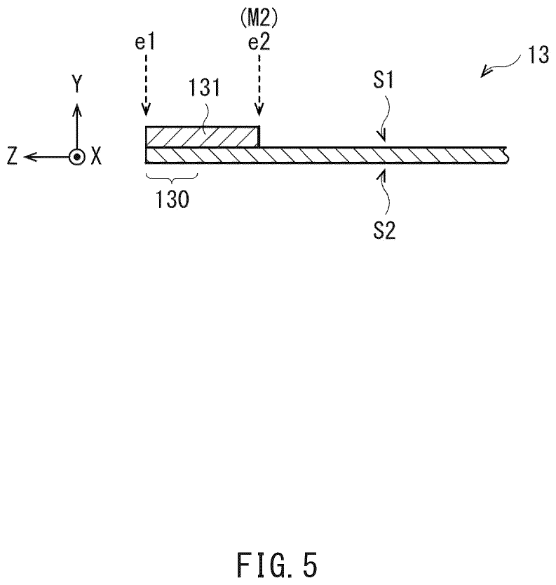

Subsequently, a detailed configuration example of the flexible boards 13a, 13b, 13c, and 13d described above will be described with reference to FIG. 4 and FIG. 5 in addition to FIG. 1 to FIG. 3.

FIG. 4 is a plan view (a Z-X plan view) schematically showing an outline configuration example of the flexible boards 13a to 13d (hereinafter collectively referred to as flexible boards 13 as appropriate) shown in FIG. 2 and FIG. 3. FIG. 5 is a cross-sectional view (a Y-Z cross-sectional view) schematically showing an outline configuration example of the flexible boards 13 shown in FIG. 4.

First, the flexible boards 13 are each formed as a double-sided board with a multilayered structure including the obverse surface S1 and a reverse surface S2. Specifically, the flexible boards 13 each have a first wiring layer at the obverse surface S1 side and a second wiring layer at the reverse surface S2 side opposed to each other along a direction (the Y-axis direction) perpendicular to a board surface (a Z-X plane) as wiring layers of such a multilayer structure (a double-layered structure).

It should be noted that it is possible to adopt a structure in which the wiring layers in the flexible board 13 are, for example, three or more layers including the first wiring layer and the second wiring layer described above.

Further, as shown in FIG. 4 and FIG. 5, the flexible boards 13 each have the single drive device 41 or the plurality of drive devices 41 (three drive devices 41 in this example) described above, wiring patterns 42, a terminal section 130, and a reinforcing plate 131.

As described above, the drive devices 41 are disposed on (the first wiring layer at the obverse surface S1 side of) the flexible board 13. Further, in the example shown in FIG. 4, the plurality of drive devices 41 (the three drive devices 41 in this example) is arranged side by side along the X-axis direction on the flexible board 13.

As shown in FIG. 4, the wiring patterns 42 are patterns of a variety of wiring lines to electrically be coupled to the drive devices 41. As the wiring patterns 42, there are included signal wiring patterns 42s corresponding to wiring lines of a variety of signals, power supply wiring patterns 42d corresponding to wiring lines of a variety of power supplies, and ground wiring patterns 42g corresponding to the ground wiring lines.

The terminal section 130 is arranged (see FIG. 4) in an end-portion region at the I/F board 12 side in the obverse surface S1 of the flexible board 13, and includes a plurality of terminals for electrically coupling the flexible board 13 and the I/F board 12 to each other. In other words, the terminal section 130 is a portion to be inserted into one of the connectors 120a to 120d on the I/F board 12 described above.

The reinforcing plate 131 is a member which is disposed including the terminal section 130 at a first end portion e1 side on the flexible board 13 (on the first wiring layer at the obverse surface S1 side) (see FIG. 4 and FIG. 5), and which adjusts the thickness of a board surface of the flexible board 13. Further, it is arranged that a second end portion e2 which is an opposite side to the first end portion e1 (a side close to an arrangement area of the drive device 41) in the reinforcing plate 131 functions as a predetermined marking portion (a second marking portion M2) described below.

It should be noted that this reinforcing plate 131 corresponds to a specific example of a “reinforcing member” in the present disclosure.

### [Configuration Example Related to Marking Portion for Visual Confirmation of Coupling State Between Boards]

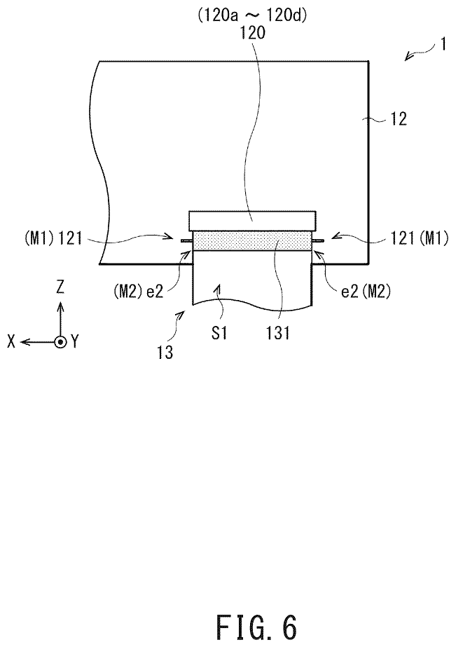

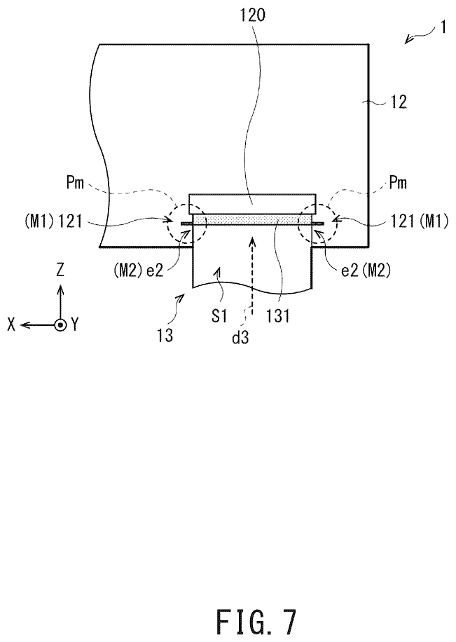

Subsequently, a configuration example related to predetermined marking portions (a first marking portion M1 and a second marking portion M2) will be described in detail with reference to FIG. 6 and FIG. 7 in addition to FIG. 1 to FIG. 5.

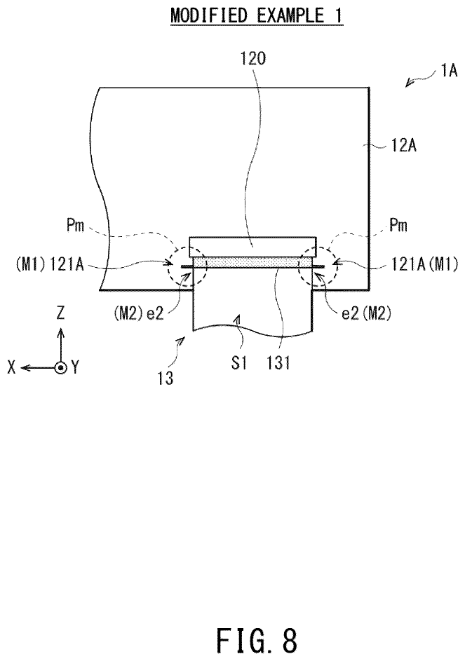

FIG. 6 and FIG. 7 are each a schematic plan view (a Z-X plan view) illustrating coupling between the boards (the I/F board 12 and the flexible board 13) according to the present embodiment. Specifically, FIG. 6 schematically shows a midway state when the terminal section 130 on the flexible board 13 is inserted into the connectors 120a to 120d (hereinafter collectively referred to as connectors 120 as appropriate) on the I/F board 12. Meanwhile, FIG. 7 schematically shows a state (a coupling state between the connector 120 and the terminal section 130) in which the terminal section 130 on the flexible board 13 is inserted into the connector 120 on the I/F board 12 (see the arrow d3 in an insertion direction represented by the broken line in FIG. 7). It should be noted that in FIG. 6 and FIG. 7 described above (and FIGS. 8 to 12 to be described below), the configuration is illustrated with a part thereof simplified for the sake of convenience.

As shown in FIG. 6 and FIG. 7, in the inkjet head 1 according to the present embodiment, the predetermined marking portions (the first marking portion M1 and the second marking portion M2) are disposed on each of the I/F board 12 and the flexible board 13. Specifically, the first marking portion M1 which is an index when visually confirming the coupling state between the connector 120 and the terminal section 130 described above is disposed on the I/F board 12. Meanwhile, the second marking portion M2 which is an index when visually confirming the coupling state between the connector 120 and the terminal section 130 described above is disposed on the flexible board 13.

Further, at least one of such first marking portion M1 and second marking portion M2 is configured using a patterning portion formed on the I/F board 12 or the flexible board 13. Specifically, in the example shown in FIG. 6 and FIG. 7, the first marking portion M1 is configured using a printed pattern portion 121 (a pattern portion with serigraph) as a patterning portion formed on the I/F board 12 (a rigid board). Further, the patterning portion (the printed pattern portion 121) is configured using the same material as the material of, for example, other patterning portions (a printed pattern portion for information display, a wiring pattern portion, and so on) formed on the same circuit board (the I/F board 12). It should be noted that a pattern width in such a printed pattern portion 121 is, for example, no smaller than several tens of micrometers as a visible width.

Meanwhile, in the example shown in FIG. 6 and FIG. 7, the second marking portion M2 is configured using the reinforcing plate 131 disposed on the flexible board 13. Specifically, as described above, it is configured that the second end portion e2 in the reinforcing plate 131 functions as the second marking portion M2.

It should be noted that it is configured that each of the arrangement areas in such first marking portion M1 and second marking portion M2 can be confirmed in, for example, a plan view.

Here, these first marking portion M1 and second marking portion M2 are each disposed at a position forming an index when visually confirming the coupling state between the connector 120 and the terminal section 130 described above (a normal insertion state of the terminal section 130 to the connector 120). It should be noted that the “normal insertion state” means an insertion states excluding abnormal insertion state (e.g., an oblique insertion state or an incomplete insertion state) of the terminal section 130 to the connector 120. Specifically, the first marking portion M1 and the second marking portion M2 are each arranged so that the normal insertion state described above can be confirmed in a plan view with respect to the first marking portion M1 and the second marking portion M2 (see the symbols Pm in FIG. 7). Particularly, in the example shown in FIG. 6 and FIG. 7, there is adopted an aspect in which the first marking portion M1 and the second marking portion M2 are confirmed in a state in which the marking portions are adjacent to each other in a plan view (at a position where the marking portions are parallel to each other).

It should be noted that the connectors 120 (120a to 120d) described above correspond to a specific example of a “connector” in the present disclosure. Further, the I/F board 12 described above corresponds to a specific example of a “first circuit board” and a “rigid board” in the present disclosure, and the flexible boards 13 (13a to 13d) described above correspond to a specific example of a “second circuit board” in the present disclosure. Further, a combination of these I/F board 12 and flexible board 13 corresponds to a specific example of a “circuit board” in the present disclosure. Further, the printed pattern portion 121 described above corresponds to a specific example of a “patterning portion” in the present disclosure.

### [Operations, and Functions and Advantages]

### (A. Basic Operation of Printer 5)

In the printer 5, a recording operation (a printing operation) of images, characters, and so on to the recording target medium (the recording paper P or the like) is performed using such a jet operation of the ink 9 by the inkjet head 1 as described below. Specifically, in the inkjet head 1 according to the present embodiment, the jet operation of the ink 9 using a shear mode is performed in the following manner.

First, the drive devices 41 on each of the flexible boards 13 (13a, 13b, 13c, and 13d) each apply the drive voltages Vd (the drive signals Sd) to the drive electrodes (the common electrodes and the active electrodes) described above in the actuator plate 111 in the jet section 11. Specifically, each of the drive devices 41 applies the drive voltage Vd to the drive electrodes disposed on the pair of drive walls partitioning the ejection channel described above. Thus, the pair of drive walls each deform so as to protrude toward the dummy channel adjacent to the ejection channel.

On this occasion, it results in that the drive wall makes a flexion deformation to have a V shape centering on the intermediate position in the depth direction in the drive wall. Further, due to such a flexion deformation of the drive wall, the ejection channel deforms as if the ejection channel bulges. As described above, due to the flexion deformation caused by a piezoelectric thickness-shear effect in the pair of drive walls, the volume of the ejection channel increases. Further, by the volume of the ejection channel increasing, the ink 9 is induced into the ejection channel as a result.

Subsequently, the ink 9 induced into the ejection channel in such a manner turns to a pressure wave to propagate to the inside of the ejection channel. Then, the drive voltage Vd to be applied to the drive electrodes becomes 0 (zero) V at the timing at which the pressure wave has reached the nozzle hole Hn of the nozzle plate 112 (or timing around that timing). Thus, the drive walls are restored from the state of the flexion deformation described above, and as a result, the volume of the ejection channel having once increased is restored again.

In such a manner, the pressure inside the ejection channel increases in the process that the volume of the ejection channel is restored, and thus, the ink 9 in the ejection channel is pressurized. As a result, the ink 9 shaped like a droplet is ejected (see FIG. 1) toward the outside (toward the recording paper P) through the nozzle hole Hn. The jet operation (the ejection operation) of the ink 9 in the inkjet head 1 is performed in such a manner, and as a result, the recording operation of images, characters, and so on to the recording paper P is performed.

### (B. Functions and Advantages in Inkjet Head 1)

Then, the functions and the advantages in the inkjet head 1 according to the present embodiment will be described in detail.

### (B-1. Regarding Related-Art Inkjet Head)

First, in a circuit board to be used in a general related-art inkjet head, a coupling method using a connector can be cited as one of methods for electrically coupling a plurality of boards to each other. For example, it is arranged that when one board is a flexible board and the other board is a rigid board, by mounting the connector on the rigid board, and making the shape of the terminal section in the flexible board coincide with the connector, these boards are electrically coupled to each other.

Since when coupling such connector and terminal section to each other, an abnormality (e.g., an oblique insertion state or an incomplete insertion state) of the coupling state may occur in some cases, it is necessary to confirm these coupling states by, for example, an electrical coupling confirmation or a visual confirmation to ensure the reliability. Specifically, as a method of confirming such an abnormality of the coupling state, there is cited, for example, a method of using some of wiring lines in the flexible board for the coupling detection to electrically confirm the coupling state. Further, for example, there is also cited a method of folding the flexible board side to form a recessed portion to thereby make it easy to perform appearance confirmation such as an oblique insertion state or an incomplete insertion state described above.

In recent years, under a circumstance in which the lifecycle of the product shortens due to diversification in product needs and progress in technology, a tendency of shifting from mass production to high-mix low-volume production is increasing. In the printing industry, in order to cope with the high-mix low-volume production, a need for replacement from related-art analog printing to digital printing (inkjet) is increasing. However, in order to replace the analog printing with inkjet printing, equivalent print speed is required. Therefore, it is necessary to ensure equivalent print speed by arranging a plurality of inkjet heads, and in order to make it possible to mount a plurality of inkjet heads, a reduction in size of the inkjet head and an increase in density of the nozzles are required. Therefore, since the reduction in size and weight is required for components of the circuit board to be used for the inkjet head, in many cases, coupling to the terminal section of the flexible board described above is used in the connector used inside the inkjet head.

However, in a small-sized connector, since insertion length from the terminal section is short, the oblique insertion state and the incomplete insertion state described above becomes easy to occur. Further, when performing connector coupling in a state in which the product is assembled, since the coupling between the connector and the terminal section is performed in the state in which the flexible board is bent, the coupling becomes more difficult than when coupling a simple-body board. Therefore, it is necessary to confirm coupling states of the connectors and the terminal sections between the boards after coupling these, but there are the following problems, for example.

First, in the method of electrically confirming the coupling state as described above, since the wiring lines are used for the coupling detection, the number of wiring lines available as input or output wiring lines decreases, and there occur a problem of a decrease in design freedom and a problem that the connector grows in size for ensuring the necessary number of wiring lines. Further, only with this method of electrically confirming the coupling state, it results in that it is determined that the coupling state is normal as long as the electrical coupling is ensured even when the incomplete insertion state or the oblique insertion state supposedly occurs. However, in this case, since the coupling state is not normal, the engagement force is weak, and therefore, there is a possibility that the terminal section comes away from the connector to cause a coupling failure after the assembling step when transporting or operating the inkjet head.

Further, in the method of forming the recessed portion by folding the flexible board side as described above, since folding processing is required in advance, an additional processing cost accrues. Further, since there is a possibility that broken line occurs when, for example, a through hole is disposed at the folding position, a restriction occurs in pattern design to decrease the degree of design freedom.

In this way, in the circuit board to be applied to the related-art inkjet head, it can be said that it is difficult to decrease the occurrence of the abnormality in the coupling state described above to increase the reliability while increasing the working efficiency to avoid a rise in cost when confirming the coupling state of the connector and the terminal section between the boards.

### (B-2. Functions and Advantages)

In contrast, in the inkjet head 1 according to the present embodiment, since the I/F board 12 and the flexible boards 13 (13a to 13d) as the circuit board are respectively provided with the following configurations, it is possible to obtain, for example, the following functions and advantages.

That is, in the present embodiment, first, the first marking portion M1 and the second marking portion M2 which are the indexes when visually confirming the coupling state between the connector 120 and the terminal section 130 are respectively disposed on the I/F board 12 and the flexible board 13. Thus, since it becomes possible to easily perform the visual confirmation of the coupling state described above (e.g., determination of the oblique insertion state and the incomplete insertion state) in the assembling step of the circuit boards (the I/F board 12 and the flexible board 13), the working efficiency increases. Further, since the visual confirmation of the coupling state described above can easily be performed after such an assembling step, an occurrence of the abnormality of the coupling state (e.g., an occurrence of the oblique insertion state or the incomplete insertion state described above) after the assembling step is reduced. In the circuit board to be applied to the inkjet head, in general, such an abnormality of the coupling state is apt to occur in a print operation (a scanning operation), and therefore, an effect of decreasing the occurrence of the abnormality is significant. In this way, in the present embodiment, it becomes possible to increase the reliability while avoiding a rise in cost.

Further, in the present embodiment, at least one of the first marking portion M1 and the second marking portion M2 is configured using a patterning portion formed on the I/F board 12 or the flexible board 13. Specifically, in the example shown in FIG. 6 and FIG. 7, the first marking portion M1 is configured using the printed pattern portion 121 as the patterning portion formed on the I/F board 12. Therefore, for example, when printing such as serigraph is already performed on the I/F board 12 as a specification, since an additional process is not required when disposing the first marking portion M1, it becomes possible to easily realize the avoidance of a rise in cost.

Further, in the present embodiment, when it is arranged that the patterning portion (the printed pattern portion 121) described above is configured using the same material as that of another patterning portion formed on the same circuit board (the I/F board 12), the following is achieved. That is, since another material (a dedicated material to the first marking portion M1) than such another patterning portion is not used when disposing the first marking portion M1, it becomes possible to avoid a rise in cost from the viewpoint of man-hour, a material cost, and so on.

In addition, in the present embodiment, since it is arranged to use the flexible board 13 having flexibility as the circuit board (a second circuit board) provided with the terminal section 130, the following is achieved. That is, it becomes possible to achieve a reduction in weight and thickness in the second circuit board, and it becomes possible to increase the degree of freedom of the board design in the second circuit board.

Further, in the present embodiment, since it is arranged that the second marking portion M2 described above is configured using the reinforcing plate 131 disposed on the flexible board 13, the following is achieved. That is, as shown in FIG. 4 to FIG. 7, for example, since the existing configuration in the reinforcing plate 131 such as the second end portion e2 in the reinforcing plate 131 can be used without change as the second marking portion M2, it becomes possible to easily realize the avoidance of a rise in cost.

Further, in the present embodiment, the I/F board 12 as a rigid board having rigidity is used as the circuit board (the first circuit board) provided with the connectors 120, and the first marking portion M1 described above is configured using the patterning portion (the printed pattern portion 121) formed on the I/F board 12. Thus, since it is not required to increase the manufacturing step when disposing the first marking portion M1, it becomes possible to avoid a rise in cost.

### 2. Modified Examples

Then, some modified examples (Modified Examples 1 to 4, 5-1, and 5-2) of the embodiment described above will be described. It should be noted that hereinafter, elements the same as those in the embodiment described above are denoted by the same reference symbols, and the description thereof will be omitted as appropriate.

### Modified Example 1

### (Configuration)

FIG. 8 is a schematic plan view (a Z-X plan view) illustrating coupling between boards (an I/F board 12A and the flexible board 13) provided to an inkjet head 1A according to Modified Example 1.

It should be noted that the inkjet head 1A corresponds to a specific example of the “liquid jet head” in the present disclosure, and a printer provided with this inkjet head 1A corresponds to a specific example of the “liquid jet recording apparatus” according to the present disclosure. Further, the I/F board 12A corresponds to a specific example of the “first circuit board” and the “rigid board” in the present disclosure, and a combination of this I/F board 12A and the flexible board 13 corresponds to a specific example of the “circuit board” in the present disclosure.

The inkjet head 1A according to Modified Example 1 corresponds to what is provided with the I/F board 12A instead of the I/F board 12 in the inkjet head 1 (see FIG. 6 and FIG. 7) according to the embodiment, and the rest of the configuration is made substantially the same. Further, the I/F board 12A corresponds to what is provided with a wiring pattern portion 121A which functions as the first marking portion M1 instead of the printed pattern portion 121 which functions as the first marking portion M1 in the I/F board 12 described above, and the rest of the configuration is made substantially the same. That is, the first marking portion M1 in the I/F board 12 is configured using the printed pattern portion 121 as the patterning portion on the one hand, and the first marking portion M1 in the I/F board 12A is configured using the wiring pattern portion 121A as the patterning portion on the other hand.

Such a wiring pattern portion 121A is configured using, for example, a conductive wiring pattern (a metal wiring pattern or the like) or a conductive electrode (a metal electrode or the like). Further, it may be arranged that the wiring pattern portion 121A is also formed using the same material as the material of another patterning portion (another wiring pattern or the like) formed on the same circuit board (the I/F board 12A in the example shown in FIG. 8) similarly to the printed pattern portion 121 described above.

It should be noted that an arrangement position of such a wiring pattern portion 121A which functions as the first marking portion M1 is made substantially the same as the arrangement position of the printed pattern portion 121 which functions as the first marking portion M1 described in the embodiment (see the reference symbols Pm in FIG. 8).

Here, the wiring pattern portion 121A described above corresponds to a specific example of a “patterning portion” in the present disclosure.

### (Functions and Advantages)

Also in Modified Example 1 having such a configuration, it is possible to obtain substantially the same advantages due to basically the same function as that of the embodiment.

Further, in particular in Modified Example 1, since the first marking portion M1 on the I/F board 12A is configured using the wiring pattern portion 121A as the patterning portion, the following is achieved. That is, for example, even when printing such as serigraph is not performed on the I/F board 12, since an additional process is not required when disposing the first marking portion M1, it becomes possible to easily realize the avoidance of a rise in cost.

### Modified Example 2

### (Configuration)

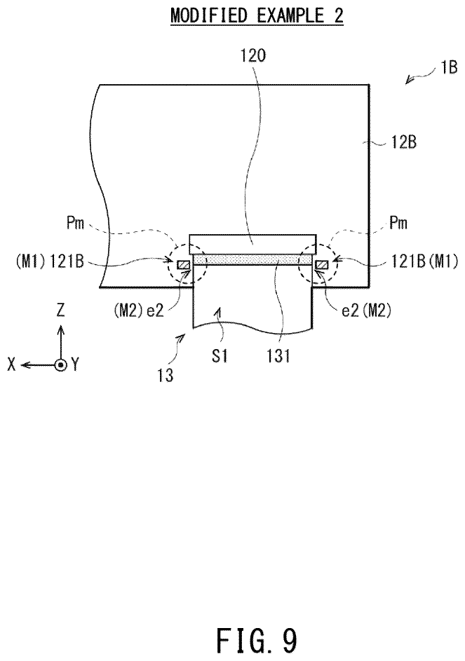

FIG. 9 is a schematic plan view (a Z-X plan view) illustrating coupling between boards (an I/F board 12B and the flexible board 13) provided to an inkjet head 1B according to Modified Example 2.

It should be noted that the inkjet head 1B corresponds to a specific example of the “liquid jet head” in the present disclosure, and a printer provided with this inkjet head 1B corresponds to a specific example of the “liquid jet recording apparatus” according to the present disclosure. Further, the I/F board 12B corresponds to a specific example of the “first circuit board” and the “rigid board” in the present disclosure, and a combination of this I/F board 12B and the flexible board 13 corresponds to a specific example of the “circuit board” in the present disclosure.

The inkjet head 1B according to Modified Example 2 corresponds to what is provided with the I/F board 12B instead of the I/F board 12 in the inkjet head 1 (see FIG. 6 and FIG. 7) according to the embodiment, and the rest of the configuration is made substantially the same. Further, the I/F board 12B corresponds to what is provided with a mounting component 121B which functions as the first marking portion M1 instead of the printed pattern portion 121 which functions as the first marking portion M1 in the I/F board 12 described above, and the rest of the configuration is made substantially the same.

Such a mounting component 121B is a component which is arranged (mounted) on the I/F board 12B, and is configured using a variety of parts such as a capacitor or a terminal member.

It should be noted that an arrangement position of such a mounting component 121B which functions as the first marking portion M1 is made substantially the same as the arrangement position of the printed pattern portion 121 which functions as the first marking portion M1 described in the embodiment (see the reference symbols Pm in FIG. 9).

### (Functions and Advantages)

Also in Modified Example 2 having such a configuration, it is possible to obtain substantially the same advantages due to basically the same function as that of the embodiment.

Further, in particular in Modified Example 2, since the first marking portion M1 on the I/F board 12B is configured using the mounting component 121B arranged on the I/F board 12B, the following is achieved. That is, for example, even when it is difficult to visually recognize the printed pattern such as serigraph, a wiring pattern, and the like on the I/F board 12B, it becomes possible to make it easy to visually recognize the first marking portion M1 to thereby be made to effectively function.

### Modified Example 3

### (Configuration)

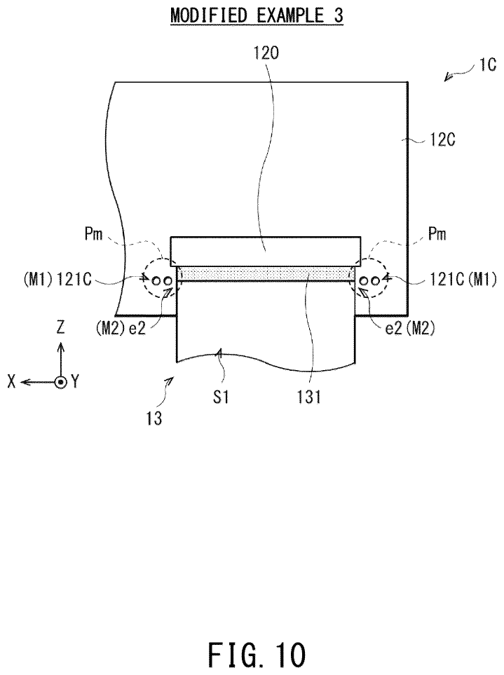

FIG. 10 is a schematic plan view (a Z-X plan view) illustrating coupling between boards (an I/F board 12C and the flexible board 13) provided to an inkjet head 1C according to Modified Example 3.

It should be noted that the inkjet head 1C corresponds to a specific example of the “liquid jet head” in the present disclosure, and a printer provided with this inkjet head 1C corresponds to a specific example of the “liquid jet recording apparatus” according to the present disclosure. Further, the I/F board 12C corresponds to a specific example of the “first circuit board” and the “rigid board” in the present disclosure, and a combination of this I/F board 12C and the flexible board 13 corresponds to a specific example of the “circuit board” in the present disclosure.

The inkjet head 1C according to Modified Example 3 corresponds to what is provided with the I/F board 12C instead of the I/F board 12 in the inkjet head 1 (see FIG. 6 and FIG. 7) according to the embodiment, and the rest of the configuration is made substantially the same. Further, the I/F board 12C corresponds to what is provided with a board processing mark (through holes 121C) which functions as the first marking portion M1 instead of the printed pattern portion 121 which functions as the first marking portion M1 in the I/F board 12 described above, and the rest of the configuration is made substantially the same.

Such through holes 121C are the board processing marks formed in an end portion of the I/F board 12C, and correspond to through holes which penetrate the I/F board 12C. It should be noted that it is possible to arrange that a board processing mark (a through hole, a cutout portion, or the like) formed in an end portion of the flexible board 13 is provided as the second marking portion M2 instead of the second end portion e2 of the reinforcing plate 131 which functions as the second marking portion M2. That is, it is possible to arrange that at least one of the first marking portion M1 and the second marking portion M2 is configured using the board processing mark formed on the I/F board 12C or the flexible board 13.

It should be noted that an arrangement position of such a through hole 121C which functions as the first marking portion M1 is made substantially the same as the arrangement position of the printed pattern portion 121 which functions as the first marking portion M1 described in the embodiment (see the reference symbols Pm in FIG. 10).

Here, the through hole 121C described above corresponds to a specific example of a “board processing mark” in the present disclosure.

### (Functions and Advantages)

Also in Modified Example 3 having such a configuration, it is possible to obtain substantially the same advantages due to basically the same function as that of the embodiment.

Further, in particular in Modified example 3, since at least one of the first marking portion M1 and the second marking portion M2 is configured using the board processing mark formed on the I/F board 12C or the flexible board 13, the following is achieved. That is, the first marking portion M1 or the second marking portion M2 can be processed and formed at the same time when processing the board in the I/F board 12C or the flexible board 13, and it becomes possible to easily realize the avoidance of a rise in cost.

Further, in the example shown in FIG. 10, since the board processing mark which forms the first marking portion M1 on the I/F board 12c is the through holes 121C, the following is achieved. That is, for example, when it is desired to dispose the first marking portion M1 in a solid pattern portion (a wiring pattern portion) such as a power supply or a ground, or when it is not desired to divide such a solid pattern portion on the I/F board 12C, it becomes possible to easily dispose the first marking portion M1.

### Modified Example 4

### (Configuration)

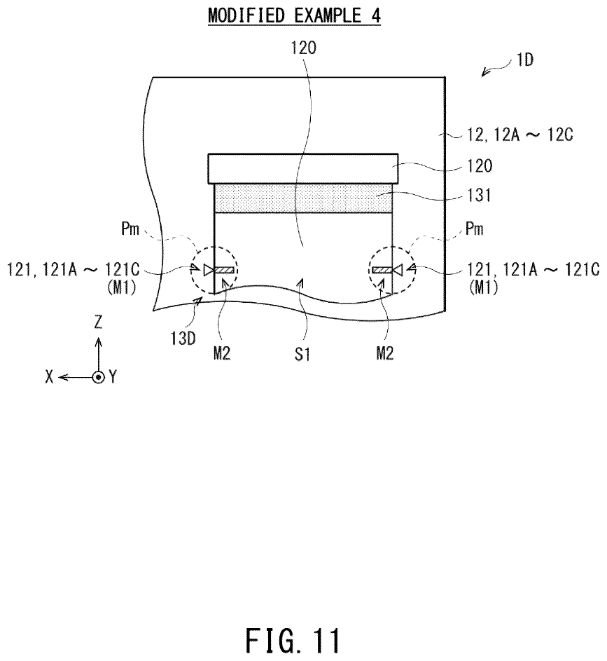

FIG. 11 is a schematic plan view (a Z-X plan view) illustrating coupling between boards (any one of the I/F boards 12 and 12A to 12C described above and a flexible board 13D) provided to an inkjet head 1D according to Modified Example 4.

It should be noted that the inkjet head 1D corresponds to a specific example of the “liquid jet head” in the present disclosure, and a printer provided with this inkjet head 1D corresponds to a specific example of the “liquid jet recording apparatus” according to the present disclosure. Further, the flexible board 13D corresponds to a specific example of the “second circuit board” in the present disclosure, and a combination of any one of the I/F boards 12 and 12A to 12C and this flexible board 13D corresponds to a specific example of the “circuit board” in the present disclosure.

The inkjet head 1D according to Modified Example 4 is what is obtained by changing in such a manner as described below in the inkjet head 1 (see FIG. 6 and FIG. 7) according to the embodiment. That is, the inkjet head 1D corresponds to what is provided with either one of the I/F boards 12 and 12A to 12C described hereinabove, and is provided with the flexible board 13D instead of the flexible board 13, and the rest of the configuration is made substantially the same.

As the first marking portion M1, any one of the printed pattern portion 121, the wiring pattern portion 121A, the mounting component 121B, and the through holes 121C (the board processing mark) described hereinabove is provided to any one of the I/F boards 12 and 12A to 12C.

In contrast, the second marking portion M2 is separately disposed on the flexible board 13D unlike the second end portion e2 of the reinforcing plate 131 on the flexible board 13. That is, on the flexible board 13D, the second marking portion M2 is not configured using the second end portion e2 of the reinforcing plate 131 but is separately disposed. As such a second marking portion M2, there can be cited, for example, a variety of patterning portions (the printed pattern portion, the wiring pattern portion, and so on), the mounting component, or a variety of board processing marks (the through hole, the cutout portion, and so on) similarly to the configuration examples of the first marking portion M1 described hereinabove.

It should be noted that in Modified Example 4 shown in FIG. 11, the first marking portion M1 and the second marking portion M2 are each arranged in substantially the same manner as in the embodiment described hereinabove. That is, the first marking portion M1 and the second marking portion M2 are each arranged so that the normal insertion state of the terminal section 130 to the connector 120 can be confirmed in a plan view with respect to the first marking portion M1 and the second marking portion M2 (see the symbols Pm in FIG. 11).

### (Functions and Advantages)

Also in Modified Example 4 having such a configuration, it is possible to obtain substantially the same advantages due to basically the same function as that of the embodiment.

### Modified Example 5

### (Configuration)

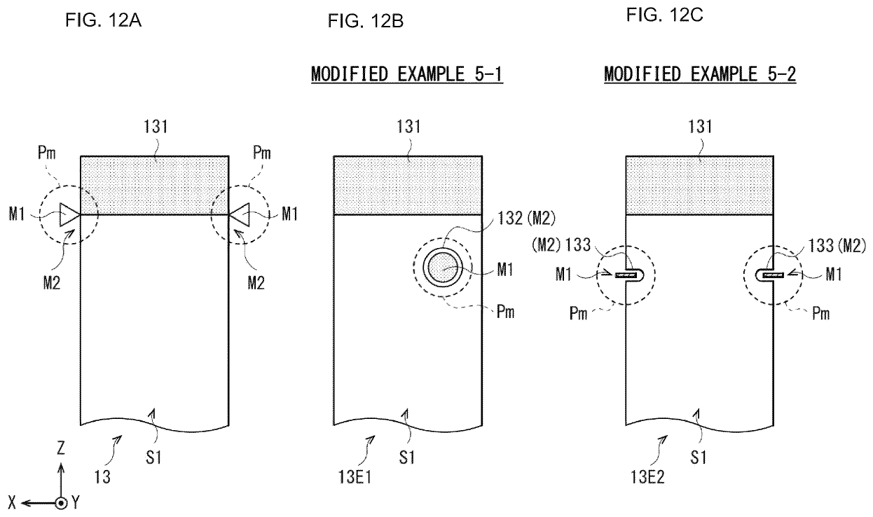

FIGS. 12A-12C are schematic plan views (a Z-X plan view) illustrating coupling between boards (any one of the I/F boards 12 and 12A to 12C described above and a flexible board 13, 13E1, or 13E2) provided to an inkjet head according to Modified Examples 5-1, 5-2. Specifically, FIG. 12A shows an example of an arrangement relationship between the second marking portion M2 in the flexible board 13 described above and the first marking portion M1 described hereinabove. Further, FIG. 12B shows an example of an arrangement relationship between the second marking portion M2 in the flexible board 13E1 related to Modified Example 5-1, and the first marking portion M1. Further, FIG. 12C shows an example of an arrangement relationship between the second marking portion M2 in the flexible board 13E2 related to Modified Example 5-2, and the first marking portion M1. It should be noted that in FIGS. 12A to 12C, the I/F board (any one of the I/F boards 12 and 12A to 12C) provided with the first marking portion M1 is omitted from the illustration for the sake of convenience.

Here, the inkjet head according to Modified Example 5-1, 5-2 corresponds to a specific example of the “liquid jet head” in the present disclosure, and a printer provided with the inkjet head according to Modified Example 5-1, 5-2 corresponds to a specific example of the “liquid jet recording apparatus” according to the present disclosure. Further, each of the flexible boards 13E1, 13E2 corresponds to a specific example of the “second circuit board” in the present disclosure. Further, a combination of any one of the I/F boards 12 and 12A to 12C and the flexible board 13E1 or the flexible board 13E2 corresponds to a specific example of the “circuit board” in the present disclosure.

First, in the flexible board 13E1 in Modified Example 5-1 shown in FIG. 12B, unlike the flexible board 13 (see FIG. 12A), the second marking portion M2 is configured using a through hole 132 as the board processing mark formed in an end portion of the flexible board 13E1. Further, in the flexible board 13E2 in Modified Example 5-2 shown in FIG. 12C, unlike the flexible board 13 (see FIG. 12A), the second marking portion M2 is configured using a cutout portion 133 as the board processing mark formed in an end portion of the flexible board 13E2.

Also in Modified Examples 5-1, 5-2, the first marking portion M1 and the second marking portion M2 are respectively arranged in substantially the same manner as in the embodiment described hereinabove. That is, the first marking portion M1 and the second marking portion M2 are each arranged so that the normal insertion state of the terminal section 130 to the connector 120 can be confirmed in a plan view with respect to the first marking portion M1 and the second marking portion M2. Specifically, in Modified Example 5-1, it is arranged that the normal insertion state described above can be confirmed by observing the first marking portion M1 in a plan view through the through hole 132 as the second marking portion M2 (see the reference symbol Pm in FIG. 12B). Meanwhile, in Modified Example 5-2, it is arranged that the normal insertion state described above can be confirmed by observing the first marking portion M1 in a plan view through the cutout portion 133 as the second marking portion M2 (see the reference symbols Pm in FIG. 12C).

It should be noted that as an aspect of the plan view when confirming such a normal insertion state, such an aspect as described below can be cited. That is, there can be cited the aspect in which the normal insertion state is confirmed in a state in which the first marking portion M1 and the second marking portion M2 are adjacent to each other in a plan view as described in the embodiment and so on. Further, there can be cited the aspect in which the normal insertion state is confirmed by observing the first marking portion M1 and the second marking portion M2 through each other in a plan view as in Modified Examples 5-1, 5-2 described above. Further, besides the above, there can be cited an aspect in which the normal insertion state is confirmed by, for example, seeing through the first marking portion M1 and the second marking portion M2 each other in a plan view.

It should be noted that the through hole 132 and the cutout portion 133 described above each correspond to a specific example of the “board processing mark” in the present disclosure.

### (Functions and Advantages)

Also in Modified Examples 5-1, 5-2 having such a configuration, it is possible to obtain substantially the same advantages due to basically the same function as that of the embodiment.

Further, when the board processing mark which forms the second marking portion M2 on the flexible board 13E2 is the cutout portion 133 which is formed in the end portion of the flexible board 13E2 as in, for example, Modified Example 5-2, the following is achieved. That is, the second marking portion M2 can be processed and formed at the same time when forming a board shape in the flexible board 13E2, and it becomes possible to easily realize the avoidance of a rise in cost.

### 3. Other Modified Examples

The present disclosure is hereinabove described citing the embodiment and some modified examples, but the present disclosure is not limited to the embodiment and so on, and a variety of modifications can be adopted.

For example, in the embodiment and so on described above, the description is presented specifically citing the configuration examples (the shapes, the arrangements, the number and so on) of each of the members in the printer and the inkjet head, but those described in the above embodiment and so on are not limitations, and it is possible to adopt other shapes, arrangements, numbers and so on.

Specifically, for example, in the embodiment and so on described above, the description is presented specifically citing the configuration examples (the shapes, the arrangement, the number of pieces, and so on) of an variety of circuit boards (the flexible boards and the rigid boards), the drive devices, and a variety of wiring patterns, but these configuration examples are not limited to those described in the above embodiment and so on. For example, in the embodiment and so on described above, there is described the example when the plurality of circuit boards (the circuit boards formed of the combination of the I/F board and the flexible board) is disposed inside the inkjet head, but this example is not a limitation, and it is possible to arrange that, for example, just one drive board is disposed inside the inkjet head. Further, in the embodiment and so on described above, there is described the example when the plurality of drive devices is disposed on the circuit board, but this example is not a limitation, and it is possible to arrange that, for example, just one drive device is disposed on the circuit board. Further, in the embodiment and so on described above, the shape of the drive device is assumed to be the rectangular shape, but this example is not a limitation, and the shape of the drive device can be, for example, a square shape. In addition, in the embodiment and so on described above, the configuration example of the marking portions (the first marking portion M1 and the second marking portion M2) is described specifically citing a variety of examples, but the configuration examples cited in the embodiment and so on described above are not a limitation, and other configuration examples may be adopted.

Further, a variety of types of structures can be adopted as the structure of the inkjet head. Specifically, it is possible to adopt, for example, a so-called side-shoot type inkjet head which ejects the ink 9 from a central portion in the extending direction of each of the ejection channels in the actuator plate 111. Alternatively, it is possible to adopt, for example, a so-called edge-shoot type inkjet head for ejecting the ink 9 along the extending direction of each of the ejection channels. Further, the type of the printer is not limited to the type described in the above embodiment and so on, and it is possible to apply a variety of types such as an MEMS (Micro Electro-Mechanical Systems) type.

Further, for example, it is possible to apply the present disclosure to either of an inkjet head of a circulation type which uses the ink 9 while circulating the ink 9 between the ink tank and the inkjet head, and an inkjet head of a non-circulation type which uses the ink 9 without circulating the ink 9.

Further, the series of processing described in the above embodiments and so on can be arranged to be performed by hardware (a circuit), or can also be arranged to be performed by software (a program). When it is arranged that the series of processing is performed by the software, the software is constituted by a program group for making the computer perform the functions. The programs can be incorporated in advance in the computer described above to be used by the computer, for example, or can also be installed in the computer described above from a network or a recording medium to be used by the computer.

Further, in the embodiment and so on described above, the description is presented citing the printer 5 (the inkjet printer) as a specific example of the “liquid jet recording apparatus” in the present disclosure, but this example is not a limitation, and it is also possible to apply the present disclosure to other apparatuses than the inkjet printer. In other words, it is also possible to arrange that the “liquid jet head” (the inkjet head) of the present disclosure is applied to other apparatuses than the inkjet printer. Specifically, it is also possible to arrange that the “liquid jet head” of the present disclosure is applied to an apparatus such as a facsimile or an on-demand printer.

In addition, it is also possible to apply the variety of examples described hereinabove in arbitrary combination.

It should be noted that the advantages described in the present specification are illustrative only, but are not a limitation, and other advantages can also be provided.

What is claimed is:

1. A circuit board configured to output a drive signal to be applied to a liquid jet head, comprising:
a first circuit board having a connector; and
a second circuit board having a terminal section as a portion to be inserted into the connector, wherein
a first marking portion which is an index when visually confirming a coupling state between the connector and the terminal section is disposed on the first circuit board, and
a second marking portion which is an index when visually confirming the coupling state is disposed on the second circuit board.

2. The circuit board according to claim 1, wherein
at least one of the first marking portion and the second marking portion is configured using a patterning portion formed on the first circuit board or the second circuit board.

3. The circuit board according to claim 2, wherein
the patterning portion is formed using a same material as a material of another patterning portion formed on a same circuit board.

4. The circuit board according to claim 2, wherein
the patterning portion is a printed pattern portion.

5. The circuit board according to claim 2, wherein
the patterning portion is a wiring pattern portion.

6. The circuit board according to claim 1, wherein
the first marking portion is configured using a mounting component arranged on the first circuit board.

7. The circuit board according to claim 1, wherein
the second circuit board is a flexible board having flexibility.

8. The circuit board according to claim 7, wherein
the second marking portion is configured using a reinforcing member arranged on the flexible board.

9. The circuit board according to claim 1, wherein
the first circuit board is a rigid board having rigidity, and
the first marking portion is configured using a patterning portion formed on the rigid board.

10. The circuit board according to claim 1, wherein
at least one of the first marking portion and the second marking portion is configured using a board processing mark formed on the first circuit board or the second circuit board.

11. The circuit board according to claim 10, wherein
the board processing mark is a cutout portion formed in an end portion of the first circuit board or the second circuit board.

12. The circuit board according to claim 10, wherein
the board processing mark is a through hole.

13. The circuit board according to claim 1, wherein
the first marking portion and the second marking portion are each disposed at a position which is an index when visually confirming a normal insertion state of the terminal section to the connector as the coupling state.

14. The circuit board according to claim 13, wherein
the first marking portion and the second marking portion are each arranged so that the normal insertion state is confirmed in a plan view with respect to the first marking portion and the second marking portion.

15. A liquid jet head comprising:
the circuit board according to claim 1; and
a jet section which is configured to jet a liquid based on the drive signal output from the circuit board, and which has a plurality of nozzles.

16. A liquid jet recording apparatus comprising:
the liquid jet head according to claim 15.
